(19) United States
(12) Patent Application Publication
(10) Pub. No.: US 2021/0146718 A1
(43) Pub. Date: May 20, 2021

(54) DISPLAY SUBSTRATE, DISPLAY PANEL, AND DISPLAY METHOD

(71) Applicant: BOE TECHNOLOGY GROUP CO., LTD., Beijing (CN)

(72) Inventors: Xiying ZHANG, Beijing (CN); Zijun LIU, Beijing (CN)

(21) Appl. No.: 16/623,000

(22) PCT Filed: Mar. 22, 2019
(86) PCT No.: PCT/CN2019/079200

§ 371 Date: Dec. 16, 2019

(30) Foreign Application Priority Data
Mar. 23, 2018 (CN) 201810246468.7

(51) Int. Cl. B44F 11/02; H01L 27/32; H01L 27/15

(52) U.S. Cl. CPC B44F 11/02; G02F 1/133514; H01L 27/156; H01L 27/3232

(57) ABSTRACT

A display substrate, a display panel and a display method are provided. The display substrate includes a display layer, a plurality of optical layer formation units and a spacer layer. The display layer includes a plurality of pixel regions, and each of the plurality of pixel regions includes a plurality of color sub-pixel openings emitting color light of different colors. The plurality of optical layer formation units are stacked with the display layer. The spacer layer is between the display layer and the plurality of optical layer formation units for spacing the display layer from the plurality of optical layer formation units. The plurality of optical layer formation units are configured to form a transparent optical layer on a side, which is away from the display layer, of the spacer layer, and the transparent optical layer is configured to make a display image have visual roughness.

### CROSS-REFERENCE TO RELATED PATENT APPLICATIONS

This application is a U.S. National Stage Application under 35 U.S.C. § 371 of International Patent Application No. PCT/CN2019/079200 filed Mar. 22, 2019, which claims priority of the Chinese Patent Application No. 201810246468.7, filed on Mar. 23, 2018, both of which are incorporated herein by reference in their entireties as part of the present application.

### TECHNICAL FIELD

The present disclosure relates to a display technical field, particularly, relates to a display substrate, a display panel and a display method.

### BACKGROUND

In the existing electronic picture frame technology, a painting may be displayed with high definition, but because of a display mode of liquid crystal display, an original material of the painting may not be presented, that is, a texture and quality of the painting may not be expressed. For example, if an original painting is an oil painting, the electronic picture frame may only display a two-dimensional painting, but senses of gradation and solidification which are formed by stacked pigments of the oil painting may not be expressed. Or, a painting created with ink may not present a sense of concavity and convexity of after the ink is dried up on paper. Although the above-mentioned defects may be made up by using 3D display technology, the existing 3D technology still cannot express the texture and quality of details excellently.

### SUMMARY

At least one embodiment of the present disclosure provides a display substrate, which includes a display layer, a plurality of optical layer formation units and a spacer layer. The display layer includes a plurality of pixel regions, and each of the plurality of pixel regions comprises a plurality of color sub-pixel openings emitting color light of different colors. The plurality of optical layer formation units are stacked with the display layer. The spacer layer is between the display layer and the plurality of optical layer formation units and configured to space spacing the display layer from the plurality of optical layer formation units. The plurality of optical layer formation units are configured to form a transparent optical layer on a side, which is away from the display layer, of the spacer layer, and the transparent optical layer is configured to make a display image have visual roughness.

For example, the display substrate provided by at least one embodiment of the present disclosure further includes a substrate, which is configured as the spacer layer and includes a first surface and a second surface which are opposite to each other. The display layer is arranged on the first surface and comprises a plurality of color filters which are respectively arranged in the plurality of color sub-pixel openings. And the plurality of optical layer formation units are arranged on the second surface at intervals.

For example, the display substrate provided by at least one embodiment of the present disclosure further includes a substrate and the display layer is on the substrate. The display layer comprises a plurality of color light emitting devices which emit color light of different colors and are respectively in the plurality of color sub-pixel openings. And the spacer layer is on a side, which is away from the substrate, of the plurality of color light emitting devices and covers the plurality of color light emitting devices.

For example, in the display substrate provided by at least one embodiment of the present disclosure, the plurality of optical layer formation units are in one-to-one correspondence with the plurality of pixel regions. The plurality of optical layer formation units are configured to form a plurality of the transparent optical layers, and the plurality of transparent optical layers are in one-to-one in correspondence with the plurality of pixel regions.

For example, in the display substrate provided by at least one embodiment of the present disclosure, each of the plurality of transparent optical layers has an orthographic projection on the display layer at least partially overlapping with a corresponding pixel region of the plurality of pixel regions, and at least two of the plurality of transparent optical layers have different thicknesses.

For example, in the display substrate provided by at least one embodiment of the present disclosure, each of the plurality of pixel regions further comprises a black matrix defining the plurality of color sub-pixel openings, and the orthographic projection of each of the plurality of optical layer formation units on the display layer is within a range of the black matrix.

For example, in the display substrate provided by at least one embodiment of the present disclosure, each of the plurality of pixel regions further comprises a white sub-pixel opening emitting white light, and the orthographic projection of each of the plurality of optical layer formation units on the display layer at least partially overlaps with the white sub-pixel opening.

For example, in the display substrate provided by at least one embodiment of the present disclosure, each of the plurality of optical layer formation units comprises a storage micro-cavity, a valve and a drive structure. The storage micro-cavity stores a transparent organic material and a first solvent, the valve is arranged on the storage micro-cavity, and the drive structure is configured to drive the valve to open so as to release the transparent organic material and the first solvent to forming the transparent optical layer and configured to drive the valve to close so as to stop releasing the transparent organic material and the first solvent.

For example, in the display substrate provided by at least one embodiment of the present disclosure, the storage micro-cavity comprises a solute chamber and a solvent chamber. The solute chamber is provided with the transparent organic material, and the solvent chamber is provided with the first solvent.

For example, in the display substrate provided by at least one embodiment of the present disclosure, the storage micro-cavity further comprises a mixing chamber. The mixing chamber is in communication with the solute chamber and the solvent chamber, and is configured to mix a transparent organic material released by the solute chamber and a first solvent released by the solvent chamber.

For example, in the display substrate provided by at least one embodiment of the present disclosure, the drive structure comprises a first micro pump or a piston.

For example, the display substrate provided by at least one embodiment of the present disclosure further includes a solvent releasing unit, which is arranged on an end of the spacer layer and configured to release a second solvent for dissolving the transparent optical layer.

For example, the display substrate provided by at least one embodiment of the present disclosure further includes an organic material recovery unit, arranged on an end, which is opposite to the solvent releasing unit, of the spacer layer and configured to recover an organic material generated after the transparent optical layer is dissolved in the second solvent.

For example, the display substrate provided by at least one embodiment of the present disclosure further includes a connection pipe, which communicates the organic material recovery unit and the storage micro-cavity and is configured to convey an organic material recovered in the organic material recovery unit to the storage micro-cavity.

For example, in the display substrate provided by at least one embodiment of the present disclosure, each of the plurality of optical layer formation units further comprises a recovery chamber, a communication pipe and a second micro pump. The recovery chamber is connected to the connection pipe and configured to receive an organic material from the organic material recovery unit; the communication pipe communicates the recovery chamber with the storage micro-cavity; and the second micro pump is configured to convey the organic material received by the recovery chamber to the storage micro-cavity through the communication pipe.

For example, the display substrate provided by at least one embodiment of the present disclosure further includes a cleaning unit. The cleaning unit is arranged on at least one end of the spacer layer and configured to clean a surface of the spacer layer, on which the transparent optical layer is formed, of the spacer layer.

For example, the display substrate provided by at least one embodiment of the present disclosure further includes a controller which is in signal connection with the drive structure of each of the plurality of optical layer formation units and is configured to provide a control signal to the drive structure for controlling a drive of the valve by the drive structure.

At least one embodiment of the present disclosure further provides a display panel, which includes the display substrate provided by any one embodiment of the present disclosure.

At least one embodiment of the present disclosure further provides a display method, which includes forming a transparent optical layer with a predetermined thickness in a region where surface roughness of an image displayed on the display panel exceeds a predetermined threshold.

For example, the display method provided by at least one embodiment of the present disclosure further includes forming the transparent optical layer in a region where visual roughness of a painting displayed on the display panel exceeds a predetermined threshold.

For example, in the display method provided by at least one embodiment of the present disclosure, the larger the visual roughness of the region of the painting is, the larger a thickness of the transparent optical layer is.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative to the disclosure.

FIG. 1A is a structural schematic diagram of a display substrate in an embodiment of the present disclosure;

FIG. 1B is a structural schematic diagram of a display substrate in another embodiment of the present disclosure;

FIG. 2A is a structural schematic diagram of a display substrate in an embodiment of the present disclosure;

FIG. 2B is a structural schematic diagram of a display substrate in another embodiment of the present disclosure;

FIG. 3 is a schematic planar diagram of a display substrate in an embodiment of the present disclosure;

FIG. 4 is a structural schematic diagram of an optical layer formation unit in further another embodiment of the present disclosure;

FIG. 5 is a structural schematic diagram of an optical layer formation unit in further another embodiment of the present disclosure;

FIG. 6A is a structural schematic diagram of an optical layer formation unit in further another embodiment of the present disclosure;

FIG. 6B is a structural schematic diagram of a structure of an optical layer formation unit in further another embodiment of the present disclosure;

FIG. 7 is a structural schematic diagram of a display substrate in further another embodiment of the present disclosure;

FIG. 8 is a structural schematic diagram of a display substrate in further another embodiment of the present disclosure;

FIG. 9 is a structural schematic diagram of a display substrate in further another embodiment of the present disclosure;

FIG. 10 is a structural schematic diagram of a display substrate in further another embodiment of the present disclosure;

FIG. 11 is a structural schematic diagram of a display substrate in further another embodiment of the present disclosure;

FIG. 12 is a structural schematic diagram of a display substrate in further another embodiment of the present disclosure;

FIG. 13 is a structural schematic diagram of a display substrate in further another embodiment of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by those of ordinary skill in the art to which the present disclosure belongs. The terms “first,” “second,” etc., which are used in the description and the claims of the present disclosure, are not intended to indicate any sequence, amount or importance, but used to distinguish various components. The terms, such as “comprise/comprising,” “include/including,” or the like are intended to specify that the elements or the objects stated before these terms encompass the elements or the objects and equivalents thereof listed after these terms, but not preclude other elements or objects. The terms, such as “connect/connecting/connected,” “couple/coupling/coupled” or the like, are not limited to a physical connection or mechanical connection, but may include an electrical connection/coupling, directly or indirectly. The terms, “on,” “under,” “left,” “right,” or the like are only used to indicate relative position relationship, and when the position of the object which is described is changed, the relative position relationship may be changed accordingly.

Embodiments of the present disclosure are described in detail below. The embodiments described below are exemplary and are only for the purpose of explaining the present disclosure, and should not be construed as limiting the present disclosure. In some embodiments where no specific technologies or conditions are indicated, they shall be carried out according to the technologies or conditions described in the literature in the field or according to the product specifications. The used reagents or instruments without manufacturer indicated are conventional products that may be purchased in the market.

It should be noted that “color light” in the embodiments does not include white light, and for example, the color light includes red light, green light, blue light, and the like.

It should be noted that “a thickness of a transparent optical layer” in the embodiments of the present disclosure refers to a thickness of a transparent optical layer in a direction perpendicular to a substrate.

It should be noted that “visual roughness” refers to a degree of fluctuation of a surface of an image (such as a painting) perceived by human eyes, which characterizes effects of roughness of a surface of a paper painting simulated by an image displayed by the display panel provided by the embodiments of the present disclosure.

At least one embodiment of the present disclosure provides a display substrate. The display substrate includes a display layer, a plurality of optical layer formation units and a spacer layer. The display layer includes a plurality of pixel regions, and each of the plurality of pixel regions comprises a plurality of color sub-pixel openings emitting color light of different colors. The plurality of optical layer formation units are stacked with the display layer. The spacer layer is between the display layer and the plurality of optical layer formation units for spacing the display layer from the plurality of optical layer formation units. The plurality of optical layer formation units are configured to form a transparent optical layer on a side, which is away from the display layer, of the spacer layer, and the transparent optical layer is configured to make a display image have visual roughness.

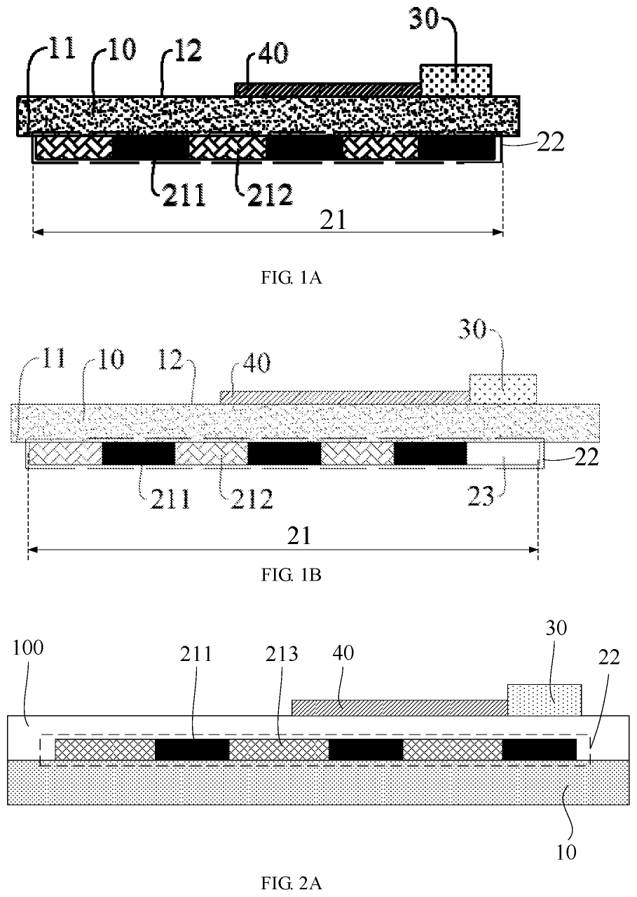

Referring to FIG. 1A, schematically, the display substrate includes a substrate 10, a display layer 22 and a plurality of optical layer formation units 30. The substrate 10 has a first surface 11 and a second surface 12 which are opposite to each other. The display layer 22 is arranged on the first surface 11 and is divided into a plurality of pixel regions 21 (only one pixel region is illustrated in the figure). Each of the plurality of pixel regions 21 includes a plurality of color sub-pixel openings emitting color light of different colors. For example, each of the plurality of pixel regions 21 further includes a black matrix 211 that defines the plurality of color sub-pixel openings. For example, the display layer 22 includes a plurality of color filters 212 respectively arranged in the plurality of color sub-pixel openings. For example, the color filters 212 in the plurality of color sub-pixel openings are respectively red filters, green filters and blue filters, and color light of different colors is respectively red light, green light and blue light. The plurality of optical layer formation units 30 are stacked with the display layer 22. For example, the plurality of optical layer formation units 30 are arranged at intervals on a side, which is away from the display layer 22, of the second surface 12 of the substrate 10, and are configured to form a transparent optical layer 40 on a side, which is away from the display layer 22, of the second surface 12, and the transparent optical layer 40 is configured to make a display image have visual roughness. In this embodiment, the substrate 10 is configured as the spacer layer, and the substrate 10 is between the display layer 22 and the plurality of optical layer formation units 30 to space the display layer 22 from the plurality of optical layer formation units 30, so that the display layer 22 is protected by the substrate 10. In a case where a display panel adopting the display substrate displays an image, for example, the image is a painting, in a case where a certain region of the painting has gradation and solidification which are formed by stacked pigments, or has concavity and convexity after ink is dried up on paper, the optical layer formation unit is controlled to form a transparent optical layer with a predetermined thickness at a position corresponding to the region on the second surface, and the transparent optical layer with the predetermined thickness can present different stereoscopic textures and qualities of the painting such as senses of gradation and solidification which are formed by stacked pigments in the painting or a sense of concavity and convexity after ink is dried up on paper, and restore an original style of the painting. For example, the optical layer formation unit forms the transparent optical layer using a transparent organic material or using a transparent organic material and a solvent.

For example, as illustrated in FIG. 1A, an orthographic projection of the transparent optical layer 40 on the substrate 10 covers a part of an orthographic projection of the color sub-pixel openings on the substrate 10; the orthographic projection of the transparent optical layer 40 on the substrate 10 may also cover orthographic projections of all of sub-pixel openings on the substrate 10 in another embodiment, which may be controlled according to requirements of the painting to be displayed.

For example, the display substrate in the embodiment illustrated in FIG. 1A is a color film substrate which may be used in a liquid crystal display device (LCD) or the like.

According to the embodiments of the present disclosure, a count of the optical layer formation units is not limited, and those skilled in the art may provide the optical layer formation units in the plurality of pixel regions according to actual requirements. For example, in at least one embodiment of the present disclosure, the optical layer formation unit 30 are arranged in one-to-one correspondence with the plurality of pixel regions 21. In a case where the display substrate is in a display operation state, the plurality of optical layer formation units 30 are configured to form a plurality of the transparent optical layers 40, and the plurality of transparent optical layers 40 are in one-to-one in correspondence with the plurality of pixel regions 21. For example, an orthographic projection of each of the plurality of transparent optical layers 40 on the display layer 22 at least partially overlaps with a corresponding pixel region of the plurality of pixel regions 21. For example, the transparent optical layer 40 has a predetermined thickness. Thicknesses of at least two of the plurality of transparent optical layers 40 are different. As a result, optical layers may be formed at any different display positions, and optical layers 40 with different predetermined thicknesses may be formed corresponding to the plurality of pixel regions 21 according to specific conditions of the display image (for example, a painting) in each of the pixel regions, such as a count of the pigments, gradation and solidification which are formed by the stacked pigments, or concavity and convexity formed after the ink is dried up on paper, so as to meet the requirements of setting the optical layers for different paintings and at different positions. In a reality painting, enlarging a cross section of the painting reveals that the pigments on its surface is not completely flat, but has fluctuation, and this fluctuation forms the texture and quality formed by the pigments of the painting. The texture and quality here refers to the visual perception that the pigments bring to human eyes. Taking an oil painting as an example, the stacking of different oil painting materials forms the fluctuation, and these materials and the fluctuation form the texture and quality of the oil painting. In an electronic painting presenting the oil painting, a picture is usually displayed with flat pixels, and the fluctuation among the pixels are almost imperceptible to human eyes, i.e. the display image does not have visual roughness. In the display substrate provided by the embodiments of the present disclosure, a transparent optical layer with a preset thickness is added on the display layer so as to simulate the texture and quality of the pigments of a paper painting and fluctuation of a surface of the painting, so that the display image has visual roughness.

For example, an orthographic projection of each of the plurality of optical layer formation units 30 on the display layer 22 does not overlap with each of the plurality of color sub-pixel openings. For example, an orthographic projection of each of the plurality of optical layer formation units 30 on the substrate 10 does not overlap with an orthographic projection of each of the plurality of color filters 212 on the substrate 10. Therefore, the optical layer formation unit 30 does not affect the transmittance of light in the plurality of color sub-pixel openings, and also does not affect the display effect of the display panel using the display substrate.

For example, in some embodiments of the present disclosure, referring to FIG. 1A, an orthographic projection of each of the plurality of optical layer formation units 30 on the substrate 10 is within an orthographic projection of the black matrix 211 on the substrate 10, that is, an orthographic projection of each of the plurality of optical layer formation units 30 on the display layer 22 is within the black matrix 211. In other embodiments of the present disclosure, for example, each of the plurality of sub-pixel openings of each pixel region 211 of the display substrate further includes a white sub-pixel opening 23 emitting white light. Referring to FIGS. 1B and 3, the optical layer formation unit 30 may be arranged at a position corresponding to the white sub-pixel opening 23, that is, an orthographic projection of the white sub-pixel opening 23 on the substrate 10 at least partially overlaps with an orthographic projection of the optical layer formation unit 30 on the substrate 10, i.e., the orthographic projection of each of the plurality of optical layer formation units 30 on the display layer 22 at least partially overlaps with the white sub-pixel opening 23. Of course, in the case where the white sub-pixel opening 23 exists, the optical layer formation unit 30 may also be arranged at a position corresponding to the black matrix 211, that is, an orthographic projection of the black matrix 211 on the substrate 10 covers an orthographic projection of the optical layer formation unit on the substrate 10 (this case is not illustrated in the figures). Thus, the optical layer formation unit 30 does not affect the transmittance of light entering the color filters (non-white filter), and thus does not affect the display effect of the display panel adopting the display substrate.

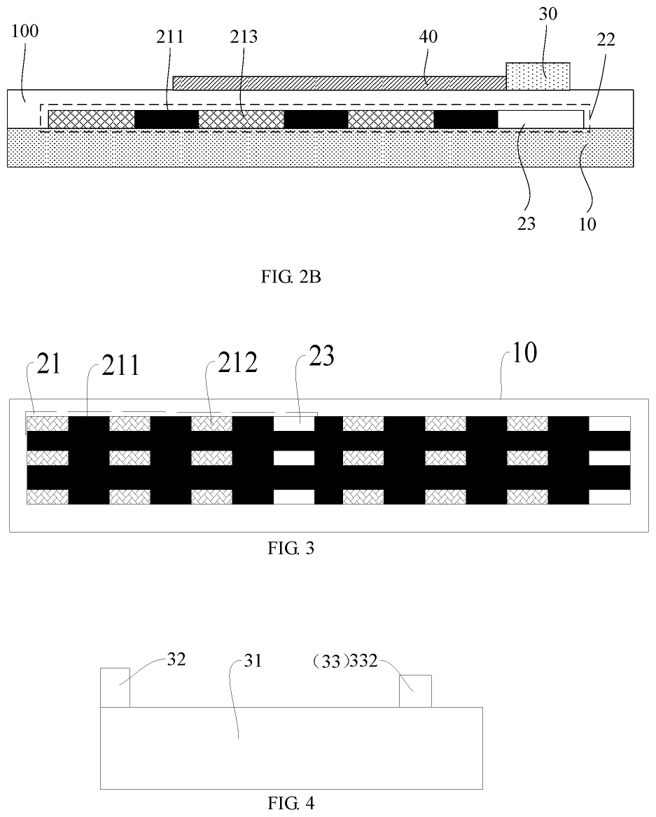

For example, in another embodiment, as illustrated in FIG. 2A, the display substrate includes a substrate 10, a display layer 22 and a plurality of optical layer formation units 30. The display layer 22 is on the substrate 10. The display layer 22 includes a plurality of color light emitting devices 213 configured to emit color light of different colors, which are respectively in a plurality of color sub-pixel openings. A spacer layer 100 is on one side, which is away from the substrate 10, of the plurality of color light emitting devices 213 and covers the plurality of color light emitting devices 213 so as to protect the plurality of color light emitting devices 213. That is, the spacer layer is between the display layer 22 and the plurality of optical layer formation units 30 so as to space the display layer 22 from the plurality of optical layer formation units 30. Of course, there may also be other layers between the spacer layer 100 and the color light emitting devices 213, for example, a sealing layer for sealing the color light emitting devices 213 or the like, which can prevent water and oxygen from contacting the color light emitting devices 213.

For example, in the embodiment illustrated in FIG. 2A, each of the plurality of color light emitting devices includes an electroluminescent element, an anode and a cathode that supply electrical signals to the electroluminescent element, etc. For example, the display substrate is a light emitting diode (LED) display substrate, such as an organic light emitting diode (OLED) display substrate or an inorganic light emitting diode display substrate, and may be used for a light emitting diode display device. Or, the color light emitting devices include another type of device capable of emitting color light.

For example, in some embodiments of the present disclosure, referring to FIG. 2B, the display substrate illustrated in FIG. 2B has the following differences from FIG. 2A. Each of the plurality of sub-pixel openings of each pixel region 211 of the display substrate further includes a white sub-pixel opening 23 emitting white light, and the optical layer formation unit 30 is arranged at a position corresponding to the white sub-pixel opening 23, that is, an orthographic projection of each of the plurality of optical layer formation units 30 on the substrate 10 at least partially overlaps with an orthographic projection of the white sub-pixel opening 23 on the substrate 10, that is, an orthographic projection of the optical layer formation unit 30 on the display layer 22 at least partially overlaps with the white sub-pixel opening 23. Of course, in the case where the white sub-pixel opening 23 exists, the optical layer formation unit 30 may also be arranged at a position corresponding to the black matrix 211, that is, an orthographic projection of the black matrix 211 on the substrate 10 covers an orthographic projection of the optical layer formation unit 30 on the substrate 10 (this case is not illustrated in the figure). Thus, the optical layer formation unit 30 does not affect the transmittance of light entering the color filters (non-white filter), and thus does not affect the display effect of the display panel adopting the display substrate.

According to the embodiments of the present disclosure, the specific type of the substrate is not limited, and it can be determined by those skilled in the art flexibly according to actual situations. In some embodiments of the present disclosure, in a case where the above display substrate is used in displays such as LCD, OLED, etc., specific types of substrates include but are not limited to metal substrates, polymer substrates, or glass substrates. In other embodiments of the present disclosure, in the case where the above display substrate is used for an LED screen, the substrate may be a transparent protective layer formed of materials such as silicon nitride, silicon oxide, and the like. Therefore, the display substrate has a wide application range.

For example, in the embodiments of the present disclosure, a material of the spacer layer is chemically stable and corrosion resistant. For example, the material of the spacer layer includes at least one of silicon nitride, silicon oxide, and silicon oxy-nitride. However, the embodiments of the present disclosure do not limit the material of the spacer layer, and those skilled in the art may flexibly select materials applicable in the field according to actual requirements. According to the embodiments of the present disclosure, the material for forming the black matrix is not limited, and those skilled in the art may flexibly select the black matrix material applicable in the field according to actual requirements. In the embodiments of the present disclosure, the material forming the black matrix includes, but is not limited to, chromium black, carbon black, mixed metal oxide, and the like.

According to the embodiments of the present disclosure, the predetermined thickness of the optical layer is not limited. Those skilled in the art may flexibly design the optical layer according to the actual requirements such as types of the pigments used in a painting and different stereoscopic textures and quality of the painting, and these are not limited herein.

For example, in an embodiment, a transparent organic material is polyisobutylene and a solvent is benzene. In this case, excessive water vapor in the display substrate can be prevented, so that the water vapor may also be prevented from entering the display layer, thereby it is beneficial to protecting the display layer. For example, in another embodiment, the transparent organic material is cellulose and the solvent is aqueous ammonium cupric hydroxide. According to the embodiments of the present disclosure, the specific type of the transparent organic materials and solvents are not limited, as long as the organic materials are transparent. A solidification time of a transparent organic material may be changed with a change of a concentration of its liquid state, for example, the solidification time is shorter with an increase of the concentration of the transparent organic material. Therefore, the concentration of the required organic material may be determined according to a distance between a forming position of the transparent optical layer and the optical layer formation unit, so as to form the transparent optical layers with predetermined thicknesses at different positions. Specifically, in a case where the solidification time is shorter with the increase of the concentration of the transparent organic material, the farther the distance between the forming position of the transparent optical layer and the optical layer formation unit is, the smaller the concentration of the transparent organic material is, and the longer the solidification time is, so that the transparent organic material has sufficient time to flow from the optical layer formation unit to the forming position of the transparent optical layer. The smaller the distance between the forming position of the transparent optical layer and the optical layer formation unit is, the larger the concentration of the transparent organic material is, and the shorter the solidification time is.

In some embodiments of the present disclosure, the organic material is degradable plastic or biodegradable material, such as lactic acid, etc., thereby, when the painting in the display panel adopting the display substrate is replaced, the transparent optical layer formed of the degradable plastic or biodegradable material is decomposed, and then the optical layer formation unit reconstructs a transparent optical layer having a predetermined refractive index according to a new painting.

In other embodiments of the present disclosure, the organic material may be polyvinyl butyral (PVB), and the solvent may dissolve PVB, such as ethanol, etc. Therefore, the solidification time of PVB with different concentrations may be different. With the increase of the concentration of the PVB, the solidification time of the PVB is shorter. However, because PVB is not easy to decompose, when the painting in the display panel adopting the display substrate is replaced, an organic material recovery device may be provided to recovery the PVB.

According to an embodiment of the present disclosure, for example, the transparent optical layer with a predetermined thickness has a predetermined refractive index. The refractive indexes of the transparent optical layers respectively formed by different concentrations of the transparent organic materials after solidification are different. Specifically, the larger the concentration is, the larger the refractive index is. The transparent optical layers with different refractive indexes formed at different positions cooperate with each other, which may further strengthen the stereoscopic texture embodied by the transparent optical layers, and the different refractive indexes may also express paintings with different pigments such as oil color, ink, crayons and the like.

According to the embodiments of the present disclosure, specific types of color filters are not limited, and those skilled in the art may flexibly select according to actual requirements. In some embodiments of the present disclosure, referring to FIG. 1A, the plurality of sub-pixel openings may include red sub-pixel openings provided with red filters, green sub-pixel openings provided with green filters, and blue sub-pixel openings provided with blue filters. In other embodiments of the present disclosure, referring to FIG. 1B, the plurality of sub-pixel openings may include red sub-pixel openings provided with red filters, green sub-pixel openings provided with green filters, blue sub-pixel openings provided with blue filters, and white sub-pixel openings provided with transparent materials. In still other embodiments of the present disclosure, the plurality of sub-pixel openings may include red sub-pixel openings provided with red filters, green sub-pixel openings provided with green filters, blue sub-pixel openings provided with blue filters, yellow sub-pixel openings provided with yellow filters, and white sub-pixel openings provided with transparent materials.

According to the embodiments of the present disclosure, the setting position of each of the optical layer formation units is not limited, as long as it is ensured that an orthographic projection of each of the plurality of optical layer formation units on the display layer does not overlap with the respective one of the plurality of sub-pixel openings.

According to the embodiments of the present disclosure, the specific structure of the optical layer formation unit is not limited, as long as it is ensured that the optical layer having a predetermined refractive index is formed at a desired position. In the embodiments of the present disclosure, referring to FIG. 4-FIG. 5 and FIG. 6A-6 FIG. B, for example, each of the plurality of optical layer formation units 30 includes a storage micro-cavity 31, a valve 32 and a drive structure 33. The storage micro-cavity 31 is provided with a transparent organic material and a first solvent. The valve 32 is arranged on the storage micro-cavity 31, and the valve 32 is configured to release the transparent organic material and the first solvent so as to form the transparent optical layer. The drive structure 33 is configured to drive the valve 32 to open so as to release the transparent organic material and the first solvent for forming the transparent optical layer and configured to drive the valve 32 to close so as to stop releasing the transparent organic material and the first solvent. Therefore, the optical layer formation unit of the structure may flexibly control the release of the transparent organic material and the solvent and a release amount thereof. Specifically, after the valve is opened, the drive structure 33 drives the release of the transparent organic material and the first solvent so as to form a transparent organic material with a certain thickness at a desired position, and after the transparent organic material is solidified, an optical layer with a predetermined thickness is obtained.

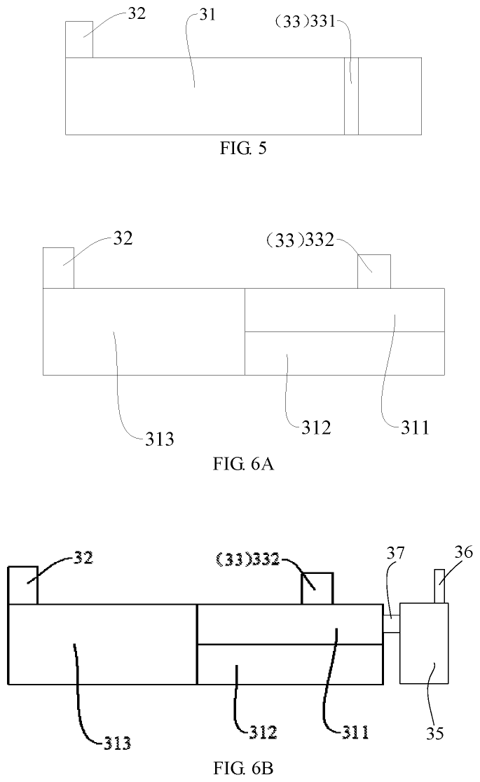

According to the embodiments of the present disclosure, a setting position of the drive structure is not limited, and may be set inside the storage micro-cavity (as illustrated in FIG. 5) or outside the storage micro-cavity (as illustrated in FIG. 4 and FIGS. 6A-6B). Those skilled in the art may flexibly select according to actual situations, and this is not limited herein.

According to the embodiments of the present disclosure, no limitation is imposed on a specific structure of the drive structure as long as it is possible to drive the valve 32 to open so as to release the transparent organic material and solvent, to provide flow power, and to drive the valve 32 to close so as to stop releasing the transparent organic material and solvent. For example, in some embodiments of the present disclosure, referring to FIG. 4, the drive structure 33 includes a first micro pump 332, such as a micro air pump (for example, fan blades), a hydraulic pump, etc. In the case where the transparent organic material and the solvent need to be released, the first micro pump presses the air into the storage micro-cavity 31, and the transparent organic material and the first solvent are released under the action of the compression of the air. For example, in some other embodiments of the present disclosure, referring to FIG. 5, the drive structure 33 includes a piston 331. In the case where the transparent organic material and the solvent need to be released, for example, the transparent organic material and the first solvent are push out by moving the piston 331 toward the valve 32. Therefore, the structure is simple and easy to control, and in a case where the transparent organic material and the first solvent are refilled, the piston 331 may be moved to an end, which is away from the valve, of the storage micro-cavity 31 so as to accommodate a maximum count of transparent organic material or solvent.

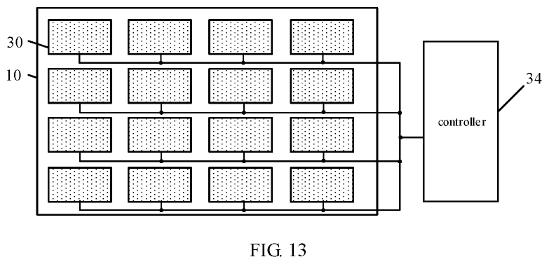

For example, in at least one embodiment of the present disclosure, there is no limitation on a manner of controlling rotation of the fan blades and a movement of the piston. Those skilled in the art may flexibly select according to actual situations. For example, the drive structure 33 also includes a motor, and the rotation of the fan blades and the movement of the piston may be driven by the motor. Or, the opening and closing of the valve are controlled by driving the first micro pump 332 to work by an electrode. For example, the valve 32 may be a mechanical valve, and a mechanical force applied to the valve 32 by the drive structure controls the movement of the valve 32 so as to realize the opening and the closing of the valve 32. For another example, the valve may also be a solenoid valve, and the opening and the closing of the solenoid valve are controlled by an electrical signal from the drive structure 33 so as to control the release of organic materials and solvents. A specific structure of the valve may be designed by those skilled in the art according to conventional techniques in the art. According to the embodiments of the present disclosure, the specific setting position of the valve is not limited, and those skilled in the art may flexibly design a position of the valve on the storage micro-cavity according to actual situations. According to the embodiments of the present disclosure, a control of opening and closing of the valve has no limitation requirements, and those skilled in the art may flexibly set according to actual requirements. For example, as illustrated in FIG. 13, the display substrate further includes a controller 34, the controller 34 is in signal connection with the drive structure 33 of each of the plurality of optical layer formation units 30, and the controller 34 is configured to provide a control signal to the drive structure 33, so as to control the drive structure 33 to drive the valve 32 to open and close. For example, the signal connection is an electrical connection, and the controller 34 is electrically connected to a drive structure 33 in each of the plurality of optical layer formation units 30, and the drive structure 33 drives the movement of the valve 32 (e.g., the rotation of the fan blades and the movement of the piston) under the control of the controller 34. Because the drive structure 33 of each of the plurality of optical layer formation units 30 is respectively connected to one output end of the controller 34, the controller 34 may output different control signals to a corresponding drive structure 33 through different output ends, thereby realizing an independent control of the operation of respective optical layer formation unit 30, so that respective position may be independently controlled according to different requirements of respective position of the painting.

For example, the controller 34 is implemented by hardware or a combination of hardware and software. For example, the controller 34 includes a drive circuit. For example, the controller 34 may be a digital processor (DSP), a programmable logic controller (PLC), or the like, and may also be a general purpose computing device such as a central processing unit (CPU), or the like. For example, demand data of each pixel region of the painting to be displayed are recorded in the controller 34. When the display panel is in operation, the controller 34 sends control signals to the plurality of optical layer formation units 30 respective corresponding to the pixel regions according to the demand data of each of the pixel regions, so as to form the optical layer with a predetermined thickness and a predetermined refractive index corresponding to respective pixel region.

According to the embodiments of the present disclosure and according to the description above, in order to obtain optical layers with predetermined thicknesses or transparent optical layers with different refractive indexes at different positions, different concentrations of the transparent organic materials need to be obtained. Referring to FIG. 6A (the drive structure in the figure takes the fan blades as an example), the storage micro-cavity 31 includes a solute chamber 311 in which the transparent organic material is provided and a solvent chamber 312 in which the first solvent is provided. Therefore, the required concentration of the transparent organic material is determined according to a required distance between the transparent optical layer and the optical layer formation units, and then the transparent organic material and the solvent are respectively released, so that various transparent organic materials with different concentrations are obtained, and after the various organic materials are solidified, optical layers with predetermined thicknesses are obtained, so as to present different stereoscopic textures of the painting such as a sense of gradation, a sense of solidification or a sense of concavity and convexity formed after the ink is dried up on paper, and restore an original style of the painting.

According to the embodiments of the present disclosure, in order to uniformly mix the respectively released transparent organic material and the first solvent, referring to FIG. 6A, for example, the storage micro-cavity 31 further includes a mixing chamber 313. The mixing chamber 313 is in communication with the solute chamber 311 and the solvent chamber 312, and is configured to mix the transparent organic material released by the solute chamber 311 and the first solvent released by the solvent chamber 312. Therefore, the transparent organic material released by the solute cavity 311 and the first solvent released by the solvent cavity 312 may be uniformly mixed, so as to obtain a transparent optical layer with a uniform refractive index. According to the embodiments of the present disclosure, in order to facilitate controlling a release of the transparent organic material, the solvent and the uniformly mixed organic material, valves and drive structures (not all illustrated in the figure) may be respectively provided in the solute chamber 311, the solvent chamber 312 and the mixing chamber 313. Therefore, independent control of different chambers is realized, organic materials with different concentrations may be obtained, and transparent optical layers with predetermined thicknesses can be obtained at different positions, so that different stereoscopic textures and quality of different paintings may be reflected.

According to the embodiments of the present disclosure, if the transparent organic material is PVB as mentioned above, in the case where the painting is replaced, because the PVB is not easy to decompose, an organic material recovery device is provided to recovery the PVB. For example, the display substrate may further include a solvent releasing unit that releases a second solvent for dissolving the transparent optical layer, so that an organic material obtained after dissolving the transparent optical layer may be recovered to reuse the organic material.

A recovery of the transparent optical layer is described in detail below according to some embodiments of the present disclosure.

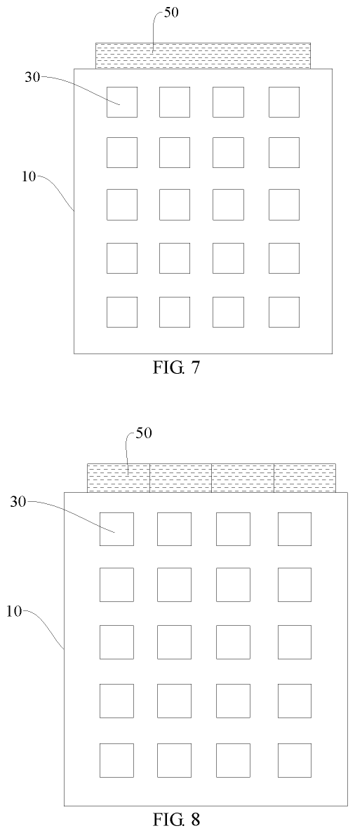

In some embodiments of the present disclosure, referring to FIG. 7, a solvent releasing unit 50 is arranged at an end of the spacer layer, for example, at an end of the substrate 10, and is configured to release a second solvent for dissolving the transparent optical layer. Therefore, the solvent releasing unit releases the solvent under control of the controller so as to dissolve the transparent optical layer, and the dissolved transparent optical layer is changed back to an organic material with fluidity, which may be reused according to requirements of an updated painting or be drained to the storage micro-cavity. If the storage micro-cavity comprises the solute chamber and the solvent chamber, for example, the organic material is drained to the solute chamber. Therefore, a utilization rate of the organic material may be improved to a greatest extent. For example, the solvent contained in the solvent releasing unit is the same as the solvent in the storage micro-cavity, so that the purity of the transparent organic material may be ensured, thereby facilitating the control of the concentration of the transparent organic material and the refractive index of the transparent optical layer formed after the transparent organic material is solidified.

According to the embodiments of the present disclosure, a count of the solvent releasing units is not limited, and those skilled in the art may flexibly select according to actual requirements. In some embodiments of the present disclosure, referring to FIG. 7, the solvent releasing unit may have a larger volume and ensure that the solvent released by the solvent releasing unit can flow to a second surface corresponding to all the pixel regions. In other embodiments of the present disclosure, referring to FIG. 8 (only four solvent releasing units are exemplarily illustrated in FIG. 8, which is not a limitation on the number of the solvent releasing units), the solvent releasing units may be a plurality of solvent releasing units that are independently controlled and each solvent releasing unit has a smaller volume, so that the solvent releasing unit which releases the solvent can be selected in a targeted way according to the arrangement of the transparent optical layer, and in this way, raw materials can be saved, a recovery time can be shortened, and a recovery amount of the organic material can be reduced.

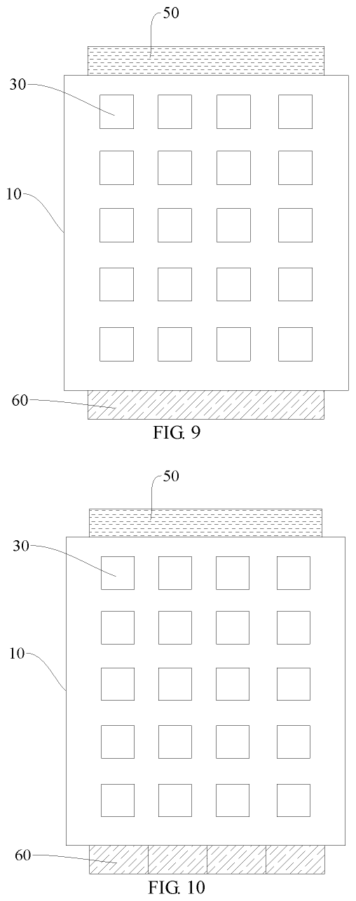

In other embodiments of the present disclosure, referring to FIG. 9, the display substrate may further include an organic material recovery unit 60 arranged at an end, which is opposite to the solvent releasing unit 50, of the spacer layer (for example, in an embodiment, the organic material recovery unit 60 is arranged at an end, which is opposite to the solvent releasing unit 50, of the substrate 10) and configured to recover the organic material generated after the transparent optical layer is dissolved in the second solvent. Therefore, the recovery of the organic material generated by dissolution of the transparent optical layer is facilitated. For example, in an embodiment, in a case where a user uses the color film substrate, the organic material recovery unit may also be arranged under the substrate 10 (a side of the substrate 10 opposite to the side on which the optical layer formation units are arranged), therefore the organic material formed after the solvent dissolves the transparent optical layer can flow into the organic material recovery unit by gravity.

According to the embodiments of the present disclosure, a count of the organic material recovery units is not limited, and those skilled in the art may flexibly select according to actual requirements. In some embodiments of the present disclosure, referring to FIG. 9, the organic material recovery unit has a larger volume, such as a cavity with larger volume, and ensures that the dissolved organic materials from all the pixel regions can be recovered. In some other embodiments of the present disclosure, referring to FIG. 10 (only four organic material recovery units are exemplarily illustrated in FIG. 10, which is not a limitation on the count of the organic material recovery units), the organic material recovery unit may include a plurality of units that are independently controlled and each of the independently controlled units has a smaller volume, for example a plurality of cavities, so that the dissolved organic materials may be selectively received in a targeted way according to the arrangement of the transparent optical layer.

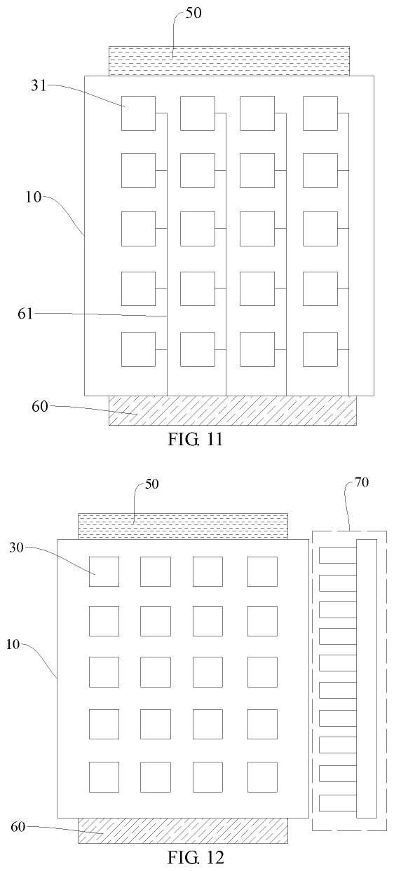

According to embodiments of the present disclosure, in order to reuse the transparent organic material recovered by the organic material recovery unit, referring to FIG. 11, the organic material recovery units may further include a connection pipe 61 which communicates the organic material recovery unit 60 and the storage micro-cavity 31, and is configured to convey the organic material recovered in the organic material recovery unit 60 to the storage micro-cavity 31. For example, as illustrated in FIG. 6B, the display substrate further includes a recovery pipe 36. The recovery pipe 36 connects the connection pipe 61 and the storage micro-cavity 31, and conveys the recovered organic material to the storage micro-cavity 31 through the connection pipe 61. Therefore, recycling of the organic material is realized.

According to the embodiments of the present disclosure, the method of draining the dissolved organic material to the storage micro-cavity is not limited, and those skilled in the art may flexibly select according to actual requirements. For example, referring to FIG. 6B, in some embodiments of the present disclosure, each of the plurality of optical layer formation units further includes a recovery chamber 35, a communication pipe 37, and a second micro pump. The recovery chamber 35 is connected to the connection pipe 61 so as to receive the organic material from the organic material recovery unit 60. For example, the recovery chamber 35 is connected to the connection pipe 61 through the recovery pipe 36 so as to receive the organic material from the organic material recovery unit 60. Or, the recovery chamber 35 is directly connected to the connection pipe 61 so as to receive the organic material from the organic material recovery unit 60. The communication pipe 3 communicates the recovery chamber 35 with the storage micro-cavity 31. The second micro pump is configured to convey the organic material received in the recovery chamber 35 to the storage micro-cavity 31 through the communication pipe 37. For example, in the embodiment illustrated in FIG. 6B, the communication pipe 37 communicates the recovery chamber 35 with the solute chamber 311, and the second micro pump is configured to convey the organic material received by the recovery chamber 35 into the solute chamber 311 through the communication pipe 37 (for example, in another embodiment, the communication pipe 37 communicates the recovery chamber 35 with the solvent chamber 312, and the second micro pump is configured to convey the organic material received by the recovery chamber 35 into the solvent chamber 312 through the communication pipe 37). For example, the second micro pump is arranged in the recovery chamber 35 or arranged in the recovery pipe 36. For example, the second micro pump is an air pump or a hydraulic pump. Therefore, the dissolved organic material is recovered into the recovery chamber 35 through the recovery pipe 36 under an action of the second micro pump, and the dissolved organic material is reused.

In some other embodiments of the present disclosure, the dissolved organic material may also be directly introduced into the recovery pipe 36, and then recovered into the solute chamber successively through the recovery chamber 35 and the communication pipe 37, and reused. The embodiments of the present disclosure do not limit the specific structure and arrangement mode of the organic material recovery unit, the recovery chamber, the recovery pipe, etc., as long as the above-mentioned effects may be achieved, and those skilled in the art may design as required. According to embodiments of the present disclosure, in order to more thoroughly recover the dissolved organic material, referring to FIG. 12, the display substrate may further include a cleaning unit 70. The cleaning unit 70 is arranged on at least one end of the spacer layer and configured to clean a surface on which the transparent optical layer is formed. For example, in the embodiments illustrated in FIGS. 1A and 1B, the cleaning unit 70 is arranged on at least one end of the substrate 10 and configured to clean the second surface of the substrate 10. Therefore, when the transparent optical layer is dissolved and recovered, the cleaning unit may clean the second surface of the substrate 10 under the control of the controller, thereby the fluidity of the dissolved organic material is increased, so that the transparent optical layer can be better dissolved in the solvent, further, the organic material can be more thoroughly recovered. Thus, waste of the organic material can be reduced, and image display quality of the display panel adopting the display substrate can be improved. According to the embodiments of the present disclosure, specific types of the cleaning unit are not limited, and those skilled in the art may flexibly select according to actual requirements. In the embodiments of the present disclosure, the cleaning units may be brushes arranged in sequence and arranged on at least one end of the substrate. For another example, in an embodiment, the cleaning unit may be arranged at two ends opposite to each other of the substrate. As a result, the organic material may be cleaned more thoroughly and cleaning efficiency may be higher.

At least one embodiment of the present disclosure further provides a display panel. According to the embodiments of the present disclosure, the display panel includes the above-mentioned display substrate. As a result, a painting displayed on the display panel may directly reflect paintings with different pigments such as oil color, ink or crayons, and may also express different stereoscopic textures and quality of the painting such as senses of gradation and solidification stacked by the pigments in the painting or a sense of concavity and convexity formed after ink dried up on paper, and restore an original style of the painting.

Those skilled in the art may understand that in addition to the above-mentioned display substrate, the display panel also has necessary structures or components of a conventional display panel. For example, the display panel may be a liquid crystal display panel. For example, the liquid crystal display panel includes the color film substrate illustrated in FIG. 1A or FIG. 1B. In addition to the above-mentioned display substrate, the liquid crystal display panel also includes a backlight source, an array substrate, a liquid crystal layer and other conventional necessary structures. For example, in the LCD display panel, a filter is on a side, which is close to the liquid crystal layer, of the substrate, and the plurality of optical layer formation units are on a side, which is away from the liquid crystal layer, of the substrate.

For example, the display panel may be an electroluminescent display panel. For example, the electroluminescent display panel includes the display substrate illustrated in FIG. 2A or FIG. 2B. For example, the electroluminescent display panel further includes a sealing layer between the spacer layer 100 and the color light emitting device 213 so as to seal the color light emitting device 213, a packaging layer, and the like.

For other structures of the display panel provided by the embodiments of the present disclosure, those skilled in the art may refer to conventional technologies.

According to the embodiments of the present disclosure, the display panel may be used in various display devices, and those skilled in the art may flexibly select according to actual situations. In the embodiments of the present disclosure, the display panel may be used in an electronic picture frame which displays a painting, so that in the case where the electronic picture frame displays a painting, the electronic picture frame may directly reflect paintings formed with different pigments such as oil color, ink or crayons, and may also express different stereoscopic textures and quality of the painting such as senses of gradation and solidification stacked by the pigments in the painting or a sense of concavity and convexity formed after ink is dried up on paper, restore an original style of the painting and improve user experience.

The embodiments of the present disclosure also provide a display method for the display panel described above. The method includes forming a transparent optical layer in a region where visual roughness of an image displayed by the display panel exceeds a predetermined threshold. For example, the transparent optical layer has a predetermined thickness. For example, thicknesses of transparent optical layers formed in different pixel regions are different. Thus, the transparent optical layer having the predetermined thickness is formed in an area where the visual roughness of the image displayed on the display substrate exceeds a predetermined threshold. For example, the image is a painting.

For example, a required concentration of the transparent organic material is determined according to a distance between the above-mentioned region and the optical layer formation unit in the pixel region to which the above-mentioned region belongs, for example, the farther the distance is, the smaller the concentration is, and the longer the solidification time is. The optical layer formation unit releases the transparent organic material with the required concentration under control of a controller, then the transparent organic material flows to the above-mentioned region and is solidified into a transparent optical layer with the predetermined thickness in the above-mentioned region. The transparent optical layer may well express paintings with different pigments such as oil color, ink or crayons, and may also better express different stereoscopic textures and quality of the painting such as senses of gradation and solidification stacked by the pigments in the painting or a sense of concavity and convexity formed after ink is dried up on paper, and restore an original style of the painting. Moreover, the display method is simple to control and easy to operate.

For example, demand data of respective pixel region of a painting to be displayed is recorded in the controller 34, and these data include, for example, visual roughness of respective pixel region, which may be characterized by, for example, a thickness of the transparent optical layer. For example, roughness of different regions on a surface of a paper painting is acquired first, and then the visual roughness of each pixel region is calculated according to the roughness, thus the required thickness of each transparent optical layer of a plurality of pixel regions is obtained. When the display panel operates, the controller 34 sends control signals to the plurality of optical layer formation units 30 corresponding to respective pixel region according to the demand data of respective pixel region, so as to form a transparent optical layer having a predetermined thickness corresponding to respective pixel region. Therefore, in the display panel provided by the embodiments of the present disclosure, the texture and quality of pigments of the paper painting and the fluctuation of the surface of the painting are simulated by the transparent optical layer having a preset thickness for forming the visual roughness of the painting, so as to express the visual perception of the texture and quality of the pigments of the paper painting and the fluctuation of the surface because of the accumulation of the pigments. According to the embodiments of the present disclosure, the thickness of the transparent optical layer is not limited, and those skilled in the art may set it according to the different texture conditions of the paintings such as senses of gradation and solidification stacked by the pigment in the painting or a sense of concavity and convexity formed after ink is dried up on paper. For example, the larger the surface roughness of the region of the painting, the larger the thickness of the transparent optical layer. If the required thickness of the transparent optical layer is relatively large and the thickness of the transparent optical layer formed by one filming process cannot reach the required thickness, the thickness of the transparent optical layer may be formed by one more filming process on the basis of the transparent optical layer formed last time, thereby increasing the thickness of the transparent optical layer, and reaching the final required thickness of the transparent optical layer.

According to the embodiments of the present disclosure, the specific value of the predetermined threshold is not limited, and those skilled in the art may flexibly select according to actual requirements such as surface roughness of paintings. In the embodiments of the present disclosure, the predetermined threshold may be 0.1 mm, 0.05 mm, 0.02 mm, etc.

In further another aspect of the present disclosure, the present disclosure provides a display device. According to the embodiments of the present disclosure, the display device includes the above-mentioned display panel. As a result, a painting displayed on the display device may directly reflect paintings with different pigments such as oil color, ink or crayons, and may also express different stereoscopic textures and quality of the painting such as senses of gradation and solidification stacked by the pigment in the painting or a sense of concavity and convexity formed after ink is dried up on paper, and restore an original style of the painting.

According to the embodiments of the present disclosure, the specific type of the display device is not particularly limited, and may be any apparatus or device with display function in the field, including but not limited to cell phones, tablet computers, computer displays, game machines, televisions, display screens, electronic picture frames for displaying paintings, wearable devices, other household appliances or household appliances with display function, etc.

Of course, those skilled in the art may understand that in addition to the display panel described above, the display device described in this disclosure may also include necessary structures and components of conventional display devices. Taking a mobile phone as an example, in addition to the display panel in this disclosure, it may also have structures and components that conventional mobile phones have, such as a touch screen, a housing, a CPU, a camera module, a fingerprint recognition module, a sound processing system and the like, which are not described in detail here. Apparently, the embodiments described above are just a part but not all the embodiments of the disclosure. Based on the described embodiments herein, those skilled in the art can obtain other embodiment(s), without any inventive work, which should be within the scope of the disclosure.

In the description of this specification, the description referring to the terms “one embodiment,” “some embodiments,” “examples,” “specific examples,” or “some examples” and the like means that a specific feature, structure, material, or characteristic described in connection with the embodiment or example is included in at least one embodiment or example of the present disclosure. In this specification, the schematic representation of the above-mentioned terms does not necessarily refer to a same embodiment or example. Moreover, the specific features, structures, materials, or characteristics described may be combined in any one or more embodiments or examples in a suitable manner. In addition, those skilled in the art may combine and compose different embodiments or examples described in this specification and features of different embodiments or examples without confliction.

The above description is only an exemplary implement of the present disclosure and is not intended to limit the scope of the present disclosure. The scope of the present disclosure is determined according to the scope defined by the accompanying claims. Those skilled in the art may make changes, modifications, substitutions and variations to the above embodiments within the scope of this disclosure.

1. A display substrate, comprising:
a display layer comprising a plurality of pixel regions, wherein each of the plurality of pixel regions comprises a plurality of color sub-pixel openings emitting color light of different colors;
a plurality of optical layer formation units stacked with the display layer; and
a spacer layer between the display layer and the plurality of optical layer formation units and configured to space the display layer from the plurality of optical layer formation units,
wherein the plurality of optical layer formation units are configured to form a transparent optical layer on a side, which is away from the display layer, of the spacer layer, and the transparent optical layer is configured to make a display image have visual roughness.

2. The display substrate according to claim 1, further comprising:
a substrate configured as the spacer layer and comprising a first surface and a second surface which are opposite to each other, wherein the display layer is on the first surface and comprises a plurality of color filters which are respectively in the plurality of color sub-pixel openings; and
the plurality of optical layer formation units are on the second surface at intervals.

3. The display substrate according to claim 1, further comprising:
a substrate, wherein the display layer is on the substrate;
the display layer comprises: a plurality of color light emitting devices which emit color light of different colors and are respectively in the plurality of color sub-pixel openings;
the spacer layer is on a side, which is away from the substrate, of the plurality of color light emitting devices and covers the plurality of color light emitting devices.

4. The display substrate according to claim 1, wherein
the plurality of optical layer formation units are in one-to-one correspondence with the plurality of pixel regions, the plurality of optical layer formation units are configured to form a plurality of the transparent optical layers, and the plurality of transparent optical layers are in one-to-one correspondence with the plurality of pixel regions.

5. The display substrate according to claim 4, wherein
each of the plurality of transparent optical layers has an orthographic projection on the display layer at least partially overlapping with a corresponding pixel region of the plurality of pixel regions, and at least two of the plurality of transparent optical layers have different thicknesses.

6. The display substrate according to claim 1, wherein
each of the plurality of optical layer formation units has an orthographic projection on the display layer not overlapping with each of the plurality of color sub-pixel openings.

7. The display substrate according to claim 6, wherein
each of the plurality of pixel regions further comprises a black matrix defining the plurality of color sub-pixel openings; and
the orthographic projection of each of the plurality of optical layer formation units on the display layer is within a range of the black matrix.

8. The display substrate according to claim 6, wherein
each of the plurality of pixel regions further comprises a white sub-pixel opening emitting white light, and the orthographic projection of each of the plurality of optical layer formation units on the display layer at least partially overlaps with the white sub-pixel opening.

9. The display substrate according to claim 1, wherein
each of the plurality of optical layer formation units comprises a storage micro-cavity, a valve and a drive structure, wherein
the storage micro-cavity stores a transparent organic material and a first solvent;
the valve is on the storage micro-cavity; and,
the drive structure is configured to drive the valve to open so as to release the transparent organic material and the first solvent to form the transparent optical layer, and configured to drive the valve to close so as to stop releasing the transparent organic material and the first solvent.

10. The display substrate according to claim 9, wherein
the storage micro-cavity comprises a solute chamber and a solvent chamber, the solute chamber being provided with the transparent organic material, and the solvent chamber being provided with the first solvent.

11. The display substrate according to claim 10, wherein
the storage micro-cavity further comprises a mixing chamber, the mixing chamber being in communication with the solute chamber and the solvent chamber, and being configured to mix a transparent organic material released by the solute chamber and a first solvent released by the solvent chamber.

12. The display substrate according to claim 9, wherein
the drive structure comprises a first micro pump or a piston.

13. The display substrate according to claim 9, further comprising:
a solvent releasing unit on an end of the spacer layer and configured to release a second solvent for dissolving the transparent optical layer.

14. The display substrate according to claim 13, further comprising:
an organic material recovery unit on an end, which is opposite to the solvent releasing unit, of the spacer layer and configured to recover an organic material generated after the transparent optical layer is dissolved in the second solvent.

15. The display substrate according to claim 14, further comprising:
a connection pipe communicating the organic material recovery unit and the storage micro-cavity and configured to convey the organic material recovered by the organic material recovery unit to the storage micro-cavity.

16. The display substrate according to claim 15, wherein
each of the plurality of optical layer formation units further comprises:
a recovery chamber connected to the connection pipe and configured to receive an organic material from the organic material recovery unit;
a communication pipe communicating the recovery chamber with the storage micro-cavity; and
a second micro pump configured to convey the organic material received in the recovery chamber to the storage micro-cavity through the communication pipe.

17. The display substrate according to claim 1, further comprising:
a cleaning unit on at least one end of the spacer layer and configured to clean a surface, on which the transparent optical layer is formed, of the spacer layer.

18. The display substrate according to claim 9, further comprising:
a controller which is in signal connection with the drive structure of each of the plurality of optical layer formation units and is configured to provide a control signal to the drive structure for controlling drive of the valve by the drive structure.

19. A display panel, comprising the display substrate according to claim 1.

20. A display method of the display panel according to claim 19, comprising:
forming the transparent optical layer in a region where visual roughness of a painting displayed by the display panel exceeds a predetermined threshold.

21. (canceled)
